(19) United States
(12) Patent Application Publication
(10) Pub. No.: US 2026/0211341 A1
(43) Pub. Date: Jul. 23, 2026

(54) LITHOGRAPHIC APPARATUS AND DEVICE MANUFACTURING METHOD

(71) Applicant: ASML NETHERLANDS B.V., Veldhoven (NL)

(72) Inventors: Manis CHAUDHURI, Eindhoven (NL); Christian Gerardus Norbertus Hendricus Marie CLOIN, Eindhoven (NL); Andrei Mikhailovich YAKUNIN, Veldhoven (NL); Marcus Adrianus VAN DE KERKHOF, Helmond (NL)

(73) Assignee: ASML NETHERLANDS B.V., Veldhoven (NL)

(21) Appl. No.: 19/135,360

(22) PCT Filed: Nov. 24, 2023
(86) PCT No.: PCT/EP2023/083065

§ 371 Date: Jun. 3, 2025

(30) Foreign Application Priority Data
Dec. 22, 2022 (EP) 22215868.5

(51) Int. Cl. G03F 7/00; G03F 7/20

(52) U.S. Cl. CPC G03F 7/70925; G03F 7/2004; G03F 7/70033; G03F 7/70066; G03F 7/702; G03F 7/70533; G03F 7/70733; G03F 7/7085; G03F 7/70933

(57) ABSTRACT

A lithographic apparatus including: an illumination system for providing a beam of EUV radiation along a beam path; a holder for a patterning device configured to impart a pattern to the beam of radiation, the patterning device comprising a patterning surface with a pattern thereon; and an electron beam source configured to emit electrons toward the patterning surface and/or a part of the beam path adjacent the patterning surface.

### CROSS-REFERENCE TO RELATED APPLICATIONS

This application claims priority of EP application 22215868.5 which was filed on 22 Dec. 2022, and which is incorporated herein in its entirety by reference.

### FIELD

The present invention relates to a lithographic apparatus and a method of manufacturing a device.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$C D = {k}_{1} * \frac{λ}{N A} \qquad ( 1 )$$

where λ is the wavelength of the radiation used, NA is the numerical aperture of the projection system used to print the pattern, k1 is a process-dependent adjustment factor, also called the Rayleigh constant, and CD is the feature size (or critical dimension) of the printed feature. It follows from Equation (1) that reduction of the minimum printable size of features can be obtained in three ways: by shortening the exposure wavelength λ, by increasing the numerical aperture NA or by decreasing the value of k1.

In order to shorten the exposure wavelength and, thus, reduce the minimum printable size, it has been proposed to use an extreme ultraviolet (EUV) radiation source. EUV radiation is electromagnetic radiation having a wavelength within the range of 10-20 nm, for example within the range of 13-14 nm. It has further been proposed that EUV radiation with a wavelength of less than 10 nm could be used, for example within the range of 5-10 nm such as 6.7 nm or 6.8 nm. Such radiation is termed extreme ultraviolet radiation or soft x-ray radiation. Possible sources include, for example, laser-produced plasma sources, discharge plasma sources, or sources based on synchrotron radiation provided by an electron storage ring.

Once the EUV radiation has been generated, it is directed through the lithographic apparatus by a plurality of mirrors to a patterning surface of the patterning device, which imparts the desired pattern to the EUV radiation. As a result of the photoelectric effect, the EUV radiation incident on the patterning surface causes electrons to be ejected from the surface, which causes the patterning surface to become positively charged.

Contaminant particles may be present in the environment surrounding the patterning device. The contaminant particles may become negatively charged by absorbing the electrons ejected from the patterning surface as a result of the photoelectric effect, and by absorbing electrons from plasma generated from gas particles that are excited by the EUV radiation.

The negatively charged contaminant particles are attracted to the positively charged patterning surface, which means that the contaminant particles are accelerated towards the patterning surface. Consequently, it is likely that contaminant particles within the environment surrounding the patterning device will be deposited onto the patterning surface. The presence of contaminant particles on the patterning surface can cause imaging errors, which reduces the yield of the lithographic process.

### SUMMARY OF THE INVENTION

An aim of the present invention is to improve the yield of an EUV lithographic process by preventing contaminant particles from being deposited on a patterning surface of a patterning device.

According to an aspect of the present invention, there is provided a lithographic apparatus comprising: an illumination system for providing a beam of EUV radiation along a beam path; a holder for a patterning device configured to impart a pattern to the beam of radiation, the patterning device comprising a patterning surface with a pattern thereon; and an electron beam source configured to emit electrons toward the patterning surface and/or a part of the beam path adjacent the patterning surface.

According to an aspect of the present invention, there is provided a device manufacturing method comprising: directing a beam of EUV radiation along a beam path to a patterning surface of a patterning device; and emitting electrons toward the patterning surface and/or a part of the beam path adjacent the patterning surface.

### BRIEF DESCRIPTION OF THE DRAWINGS

Embodiments of the invention will now be described, by way of example only, with reference to the accompanying schematic drawings, in which corresponding reference symbols indicate corresponding parts.

FIG. 1 schematically depicts a lithographic apparatus.

FIG. 2 schematically depicts a more detailed view of the lithographic apparatus.

FIG. 3 schematically depicts a patterning device whilst being exposed to EUV radiation.

FIG. 4 schematically depicts a contamination control arrangement of an embodiment.

FIG. 5 is a graph of potential of the patterning device with time in the embodiment of FIG. 4 and a comparative example.

FIG. 6 is schematic diagram of particle movement in the embodiment of FIG. 4.

FIG. 7 schematically depicts a contamination control arrangement of another embodiment.

FIG. 8 is a graph of particle radius vs particle charge for different electron energies.

FIG. 9 is a graph of particle charge vs electron: ion temperature ratio for different particle radii.

The features shown in the Figures are not necessarily to scale, and the size and/or arrangement depicted is not limiting. It will be understood that the Figures include optional features which may not be essential to the invention. Furthermore, not all of the features of the apparatus are depicted in each of the figures, and the Figures may only show some of the components relevant for describing a particular feature.

### DETAILED DESCRIPTION

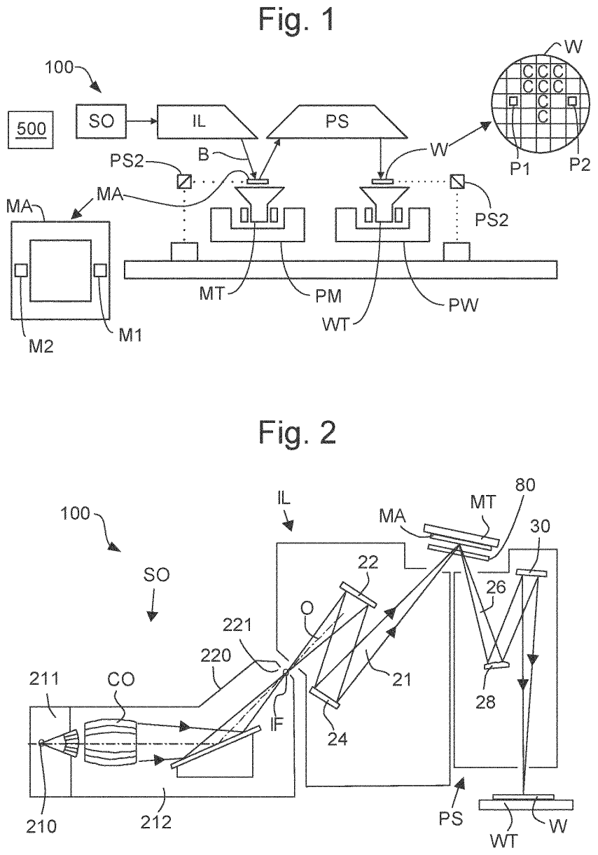

FIG. 1 schematically depicts a lithographic apparatus 100 including a source collector module SO according to one embodiment of the invention. The apparatus 100 comprises:
an illumination system (or illuminator) IL configured to condition a radiation beam B (e.g., EUV radiation).
a support structure (e.g., a mask table) MT constructed to support a patterning device (e.g., a mask or a reticle) MA and connected to a first positioner PM configured to accurately position the patterning device;
a substrate table (e.g., a wafer table) WT constructed to hold a substrate (e.g., a resist-coated wafer) W and connected to a second positioner PW configured to accurately position the substrate; and
a projection system (e.g., a reflective projection system) PS configured to project a pattern imparted to the radiation beam B by patterning device MA onto a target portion C (e.g., comprising one or more dies) of the substrate W.

The illumination system IL may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure MT can use mechanical, vacuum, electrostatic or other clamping techniques to hold the patterning device MA. The support structure MT may be a frame or a table, for example, which may be fixed or movable as required. The support structure MT may ensure that the patterning device MA is at a desired position, for example with respect to the projection system PS.

The term “patterning device” should be broadly interpreted as referring to any device that can be used to impart a radiation beam B with a pattern in its cross-section such as to create a pattern in a target portion C of the substrate W. The pattern imparted to the radiation beam B may correspond to a particular functional layer in a device being created in the target portion C, such as an integrated circuit.

Examples of patterning devices include masks, programmable mirror arrays, and programmable liquid-crystal display (LCD) panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix.

The projection system PS, like the illumination system IL, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since other gases may absorb too much radiation. A vacuum environment may therefore be provided to the whole beam path with the aid of a vacuum wall and vacuum pumps.

As here depicted, the lithographic apparatus 100 is of a reflective type (e.g., employing a reflective mask).

The lithographic apparatus 100 may be of a type having two (dual stage) or more substrate tables WT (and/or two or more support structures MT). In such a “multiple stage” lithographic apparatus the additional substrate tables WT (and/or the additional support structures MT) may be used in parallel, or preparatory steps may be carried out on one or more substrate tables WT (and/or one or more support structures MT) while one or more other substrate tables WT (and/or one or more other support structures MT) are being used for exposure.

Referring to FIG. 1, the illumination system IL receives an extreme ultraviolet radiation beam from the source collector module SO. Methods to produce EUV light include, but are not necessarily limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel, such as a droplet, stream or cluster of material having the required line-emitting element, with a laser beam. The source collector module SO may be part of an EUV radiation system including a laser, not shown in FIG. 1, for providing the laser beam exciting the fuel. The resulting plasma emits output radiation, e.g., EUV radiation, which is collected using a radiation collector, disposed in the source collector module. The laser and the source collector module SO may be separate entities, for example when a CO₂ laser is used to provide the laser beam for fuel excitation.

In such cases, the laser is not considered to form part of the lithographic apparatus 100 and the radiation beam B is passed from the laser to the source collector module SO with the aid of a beam delivery system comprising, for example, suitable directing mirrors and/or a beam expander. In other cases the source may be an integral part of the source collector module SO, for example when the source is a discharge produced plasma EUV generator, often termed as a DPP source.

The illumination system IL may comprise an adjuster for adjusting the angular intensity distribution of the radiation beam. Generally, at least the outer and/or inner radial extent (commonly referred to as o-outer and o-inner, respectively) of the intensity distribution in a pupil plane of the illumination system IL can be adjusted. In addition, the illumination system IL may comprise various other components, such as facetted field and pupil mirror devices. The illumination system IL may be used to condition the radiation beam B, to have a desired uniformity and intensity distribution in its cross-section.

The radiation beam B is incident on the patterning device (e.g., mask) MA, which is held on the support structure (e.g., mask table) MT, and is patterned by the patterning device MA. After being reflected from the patterning device (e.g., mask) MA, the radiation beam B passes through the projection system PS, which focuses the radiation beam B onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. The patterning device (e.g., mask) MA and the substrate W may be aligned using mask alignment marks M1, M2 and substrate alignment marks P1, P2.

A controller 500 controls the overall operations of the lithographic apparatus 100 and in particular performs an operation process described further below. Controller 500 can be embodied as a suitably-programmed general purpose computer comprising a central processing unit, volatile and non-volatile storage means, one or more input and output devices such as a keyboard and screen, one or more network connections and one or more interfaces to the various parts of the lithographic apparatus 100. It will be appreciated that a one-to-one relationship between controlling computer and lithographic apparatus 100 is not necessary. In an embodiment of the invention one computer can control multiple lithographic apparatuses 100. In an embodiment of the invention, multiple networked computers can be used to control one lithographic apparatus 100. The controller 500 may also be configured to control one or more associated process devices and substrate handling devices in a lithocell or cluster of which the lithographic apparatus 100 forms a part. The controller 500 can also be configured to be subordinate to a supervisory control system of a lithocell or cluster and/or an overall control system of a fab.

FIG. 2 shows the lithographic apparatus 100 in more detail, including the source collector module SO, the illumination system IL, and the projection system PS. An EUV radiation emitting plasma 210 may be formed by a plasma source. EUV radiation may be produced by a gas or vapor, for example Xe gas, Li vapor or Sn vapor in which the radiation emitting plasma 210 is created to emit radiation in the EUV range of the electromagnetic spectrum. In an embodiment, a plasma of excited tin (Sn) is provided to produce EUV radiation.

The radiation emitted by the radiation emitting plasma 210 is passed from a source chamber 211 into a collector chamber 212.

The collector chamber 212 may include a radiation collector CO. Radiation that traverses the radiation collector CO can be focused in a virtual source point IF. The virtual source point IF is commonly referred to as the intermediate focus, and the source collector module SO is arranged such that the virtual source point IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the unpatterned beam 21, at the patterning device MA, as well as a desired uniformity of radiation intensity at the patterning device MA. Upon reflection of the unpatterned beam 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in the illumination system IL and the projection system PS. Further, there may be more mirrors present than those shown in the Figures, for example there may be 1-6 additional reflective elements present in the projection system PS than shown in FIG. 2.

Alternatively, the source collector module SO may be part of an LPP radiation system.

As depicted in FIG. 1, in an embodiment the lithographic apparatus 100 comprises an illumination system IL and a projection system PS. The illumination system IL is configured to emit a radiation beam B. The projection system PS is separated from the substrate table WT by an intervening space. The projection system PS is configured to project a pattern imparted to the radiation beam B onto the substrate W. The pattern is for EUV radiation of the radiation beam B.

The space intervening between the projection system PS and the substrate table WT can be at least partially evacuated. The intervening space may be delimited at the location of the projection system PS by a solid surface from which the employed radiation is directed toward the substrate table WT.

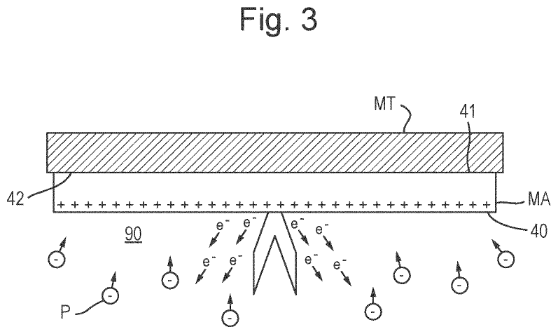

FIG. 3 depicts a schematic representation of a patterning device MA clamped to a support structure MT. As described above, the support structure MT may use mechanical, vacuum, electrostatic or other clamping techniques to hold the patterning device MA. The support structure MT may comprise a plurality of burls (cone-shaped protrusions) on a supporting surface 42 of the support structure MT that faces a non-patterning surface 41 of the patterning device MA. When the patterning device MA is clamped to the support structure MT, the non-patterning surface 41 is in contact with distal ends of the plurality of burls. It is not necessary for each of the plurality of burls to be in contact with the non-patterning surface 41. These burls are not shown in FIG. 3.

Both the patterning device MA and support structure MT may be contained within a patterning device environment 90. The patterning device environment 90 may be separated from an external environment surrounding the lithographic apparatus 100 and/or other components within the lithographic apparatus such that gases and contaminant particles P are substantially prevented from entering the patterning device environment 90.

The patterning device environment 90 may be partially evacuated of gas. That is, the pressure within the patterning device environment 90 may be less than ambient pressure. This is to limit the attenuation of EUV radiation as it travels through the patterning device environment 90. Even though the pressure within the patterning device 90 is less than ambient pressure, it is not a perfect vacuum, so gas particles are present in the patterning device environment 90.

Contaminant particles P may also be present in the patterning device environment 90. Despite the separation of the patterning device environment 90 from the external environment and/or other components within the lithographic apparatus, it is possible that some contaminant particles P may enter the patterning device environment 90 from these locations. Also, contaminant particles P may be generated within the patterning device environment 90 by mechanisms such as abrasive wear, which occurs when there is relative motion between contacting surfaces.

During EUV lithography, the unpatterned beam 21 is incident on a patterning surface 40 of the patterning device MA. This causes the release of electrons from the patterning surface 40 by the photoelectric effect. Consequently, the patterning surface 40 becomes positively charged.

The EUV radiation within the patterning device environment 90 also causes contaminant particles P to become negatively charged. This occurs as a result of at least two main mechanisms. A first mechanism is a result of the formation of plasma from the gas molecules within the patterning device environment 90, which are excited by the EUV radiation. Free electrons within the plasma may be absorbed by the contaminant particles P, resulting in those particles becoming negatively charged. A second mechanism is a consequence of the photoelectric effect which causes the patterning surface 40 to become positively charged. Specifically, electrons that have been ejected from the patterning surface 40 as a result of the photoelectric effect may be absorbed by the contaminant particles P, causing them to become negatively charged.

As a result of the patterning surface 40 becoming positively charged and the contaminant particles P becoming negatively charged, an attractive electrostatic force is exerted between the patterning surface 40 and the contaminant particles P. This causes the contaminant particles P to accelerate towards the patterning surface 40. Consequently, it is likely that contaminant particles within the lithographic apparatus will be deposited onto the patterning surface 40.

In EUV lithographic systems, EUV radiation is typically generated in pulses. That is, there are periods when EUV radiation is generated, and periods when it is not. In the periods when the EUV pulse is not generated, the patterning surface 40 may be discharged, i.e., the magnitude of the positive charge on the patterning surface 40 may decrease. This may be such that the patterning surface 40 becomes approximately neutral. The discharging of the patterning surface 40 may be caused by the plasma that is formed within the patterning device environment 90 from the gas particles excited by the EUV radiation. Specifically, electrons within the plasma may be attracted to the patterning surface 40, where they are absorbed by positive ions on the patterning surface 40. Pulses of EUV radiation are typically generated at a rapid frequency. This frequency may be, for example, approximately 50 kHz, approximately 60 kHz, or approximately 100 kHz. This means that, during an EUV lithographic process, a patterning surface 40 may cycle between being positively charged and being approximately neutral at a high frequency.

While the patterning surface is positively charged, contaminant particles P are accelerated towards the patterning surface 40 as a result of electrostatic attraction. Contaminant particles may therefore become attached to the patterning surface giving rise to imaging defects until they can be removed. However removal risks damaging the patterning surface. Therefore it is highly desirable to prevent contaminant particles contacting the patterning surface at all. To achieve this it is desirable to reduce, more desirably eliminate, the electrostatic attraction between the contaminant particles and the patterning surface.

Two approaches to reducing the electrostatic attraction are possible. One approach is to reduce the positive potential of the patterning surface 40 as quickly as possible, desirably to a zero potential relative to surrounding parts of the lithographic apparatus (e.g. masking blades 91) or even to achieve a negative potential. A negative potential will tend to repel negatively-charged contaminant particles. Another approach is to reduce the negative charge on the contaminant particles, e.g. to zero charge or neutrality. This may be referred to as quenching.

Both approaches can be accomplished by providing an electron beam source to emit cold electrons toward the patterning surface 40 of the patterning device and/or into the space where charged particles are present, e.g. a space traversed by the EUV radiation (the beam path) and close to the patterning surface 40. Cold electrons may be considered electrons having kinetic energy less than about 10 eV, desirably less than about 5 eV. Although in some cases higher energy electrons may be used, it is desirable to ensure that the energy of the electrons is not sufficiently high to risk damaging the patterning surface 40. It is desirable that the energy of the electrons is not high enough to create additional plasma, i.e. the electron energy is less than the hydrogen ionization energy. In some cases, very cold electrons, e.g. with kinetic energy less than 1 eV, e.g. about 0.1 eV, may be used.

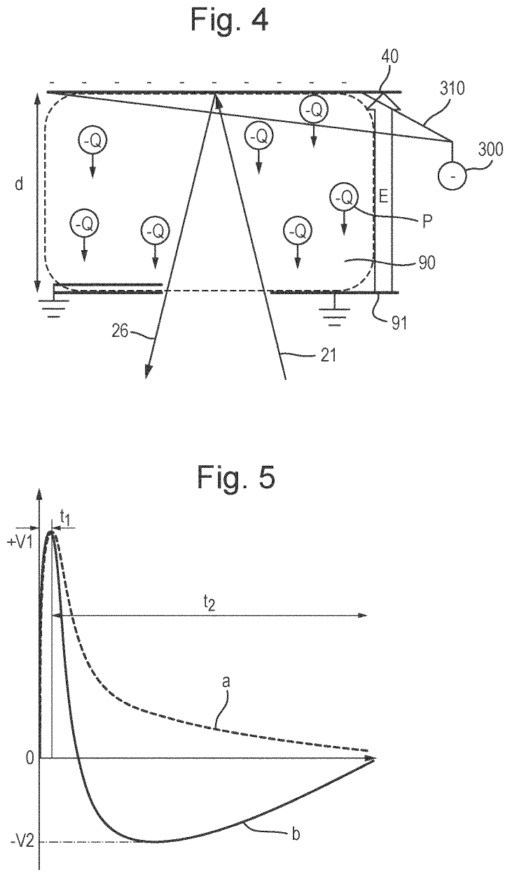

FIG. 4 depicts a first embodiment in which an electron beam source 300 that emits electrons 310 to the patterning surface 40 is provided. Electrons emitted by electron beam source 300 and impinging on the patterning surface will rapidly neutralize the positive charge on the patterning surface 40 and may even cause the patterning surface to become negatively charged, as depicted in FIG. 5. FIG. 5 shows the potential of the patterning surface in the period following an EUV pulse using the invention (solid line) and using a voltage biasing system (dashed line) in which a bias voltage is applied to the patterning surface 40. When the EUV pulse is on, the potential of the patterning surface quickly rises to a large positive value, +V1 at time t₁ when the EUV beam is turned off. When the electron beam source is turned on, the potential of the patterning surface quickly falls to a small negative potential, −V 2 and reverts to 0 at time t₂. With a voltage biasing system the potential of the reticle falls slowly from its peak at t₁ but remains positive for the whole of the period t₂. As well as reducing the potential of the patterning surface more quickly, the use of an electron beam source avoids large currents flowing through the patterning surface or the body of the patterning device. An excessively large current in the patterning surface 40 or the body of the patterning device might cause localized heating and deformation, which can reduce the quality of the pattern projected from the patterning surface 40 to the substrate W.

Electron beam source 300 is desirably synchronized with the pulsed EUV beam so that it does not emit electrons in the period whilst the EUV beam is on. This ensures that the electron beam for neutralizing the patterning device does not interfere with the exposure of substrates. Desirably, the electron beam is turned on as soon as possible after the EUV beam pulse has finished so as to neutralize the patterning device as quickly as possible. If it can be established that the operation of the electron beam source has no detrimental effect on exposures, it would be possible to operate the electron beam source continuously, which would simplify control.

The current of the electron beam does not have to be particularly high nor set or controlled very precisely. In most cases, a current of about 100 μA to 1 mA will reduce the positive potential of the patterning device quickly enough to have a discernable and advantageous effect on the number of particles impacting the patterning device. In some cases a current of several 100 mA, e.g. up to about 1 A, might be useful. A power supply of 0.05-5 W is likely to be sufficient to drive the electron beam source. Although a zero particle count is desirable, any reduction in the number of particles impinging on the patterning device is desirable as it increases yield, increases the service life of the patterning device and/or increases the interval between cleaning processes.

It is desirable that the patterning device not be driven to a high negative potential. However it is an advantage of the use of cold electrons that the negative potential is self-limiting; as the negative potential of the patterning device approaches the energy of the cold electrons, the cold electrons will be repelled by the negative potential of the patterning device. If higher energy electrons are used to drive the potential of the patterning device down more quickly, the duty cycle of the electron beam source may be controlled to ensure the patterning device does not go too negative. Control of the duty cycle of the electron beam source may be based on a real-time measurement of the potential of the patterning device, theoretical calculations, simulations or empirical tests.

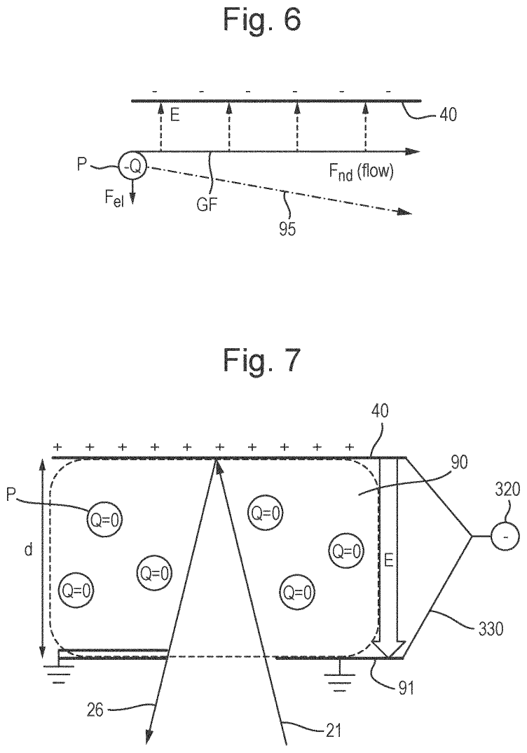

As depicted in FIG. 6, when the patterning device has a neutral, or even negative potential, relative to adjacent parts of the lithographic apparatus (e.g. masking blades, cover plates or purge gas nozzles), negatively-charged particles in the vicinity of the patterning device are no longer attracted to the patterning device or even repelled. If the potential of the patterning device is still positive, but of lower magnitude than it would be were the invention not employed, negative particles will still be attracted but less quickly.

The patterning device environment 90, in particular the environment between the patterning device and the masking blades, is not a perfect vacuum but has a low pressure of gas, e.g. hydrogen at a pressure of a few Pa. A gas supply and gas extractor are provided to establish a gas flow GF generally parallel to the surface of the patterning device. The gas flow flushes away the particles via flow-induced drag F_{nd}(flow). Because the particles are not attracted to the patterning device, or attracted more slowly, or repelled, the gas flow has more time to flush away the particles. Negatively charged particles P follow a trajectory 95 that is away from the patterning surface 40.

The electron beam source is desirably located between the patterning device and the masking blades. In such a location, the electron beam can be directed onto the patterning device directly and from a short distance, minimizing the risk of unwanted charges building up on other parts of the apparatus.

The electron beam source may comprise a wire, comb, spike, filament or other discharge device. There may be multiple electron beam sources distributed around the patterning device. The electron beam source is not large and does not have to be connected to a high voltage power supply so that there are unlikely to be difficulties in finding space for it.

In general, the electron beam source does not have to be directional; the emitted electrons will naturally be attracted toward the most positive regions of the patterning surface. However, if the patterning surface has low conductivity, there may be an advantage to directing the electron beam toward the region of the patterning surface that is undergoing illumination. The direction of the electron beam may be controlled in synchronism with the movement of masking blades that define the area of illumination of the patterning device.

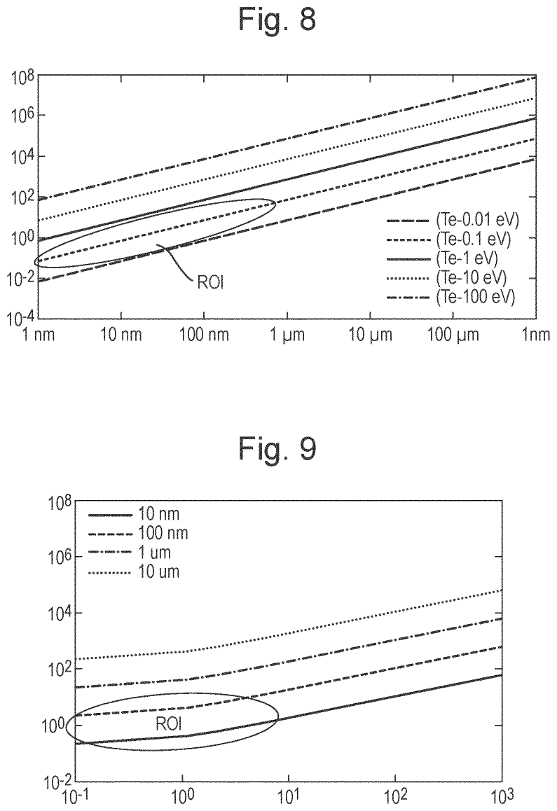

FIG. 7 depicts a second embodiment in which electron beam source 320 emits very cold electrons 330 to quench negatively-charged particles in the space in the vicinity of the patterning surface. The steady state volume charge of particles in a plasma can be described by orbital motion theory and depends on particle size and the electron to ion temperature ratio, Te/Ti. Particles that are experienced in the lithographic apparatus frequently have sizes in the range of 10 to 500 nm. FIGS. 8 and 9 show a region of interest (ROI) demonstrating that an electron temperature of between 0.01 eV and 1 eV, e.g. about 0.1 eV, can achieve a charge number of about one elementary charge per particle, which is essentially neutral. FIG. 8 depicts elementary charge count (Y-axis) vs particle diameter (X-axis) for various values of electron temperature Te. FIG. 9 depicts elementary charge count (Y-axis) vs electron to ion temperature ratio, Te/Ti, (X-axis) for various values of particle diameter. It is assumed that the ion temperature is about room temperature.

In the second embodiment, the particles are not attracted to the patterning device even if the patterning device has a positive potential because the particles are neutral. As in the first embodiment, the neutral particles are flushed away by flow in the gas in the vicinity of the patterning device.

In the second embodiment, the electron beam source can be synchronized to the EUV beam or operate continuously, as in the first embodiment. The ion beam source may comprise a wire, comb, spike, filament or other discharge device. There may be multiple electron beam sources distributed around the patterning device. The electron beam source is not large and does not have to be connected to a high voltage power supply so that there are unlikely to be difficulties in finding space for it.

The first and second embodiments may be combined using multiple electron beam sources or by applying different potentials to the electron beam source at different times.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Where the context allows, embodiments of the invention may be implemented in hardware, firmware, software, or any combination thereof. Embodiments of the invention may also be implemented by instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

Although specific reference may be made in this text to embodiments of the invention in the context of a lithographic apparatus, embodiments of the invention may be used in other apparatus.

Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools.

Although specific reference may have been made above to the use of embodiments of the invention in the context of optical lithography, it will be appreciated that the invention, where the context allows, is not limited to optical lithography.

Aspects of the invention are described in the following numbered clauses.

1. A lithographic apparatus:
an illumination system for providing a beam of EUV radiation along a beam path;
a holder for a patterning device configured to impart a pattern to the beam of radiation, the patterning device comprising a patterning surface with a pattern thereon; and
an electron beam source configured to emit electrons toward the patterning surface and/or a part of the beam path adjacent the patterning surface.
   2. The lithographic apparatus of clause 1, wherein the electron beam source is configured to emit electrons having kinetic energy less than 10 eV, desirably less than 5 eV.
   3. The lithographic apparatus of clause 1 or 2, wherein the electron beam source is configured to emit electrons in pulses.
   4. The lithographic apparatus of clause 3, wherein the electron beam source is configured to emit electrons during periods when the beam of EUV radiation is off.
   5. The lithographic apparatus of any of clauses 1 to 4, further comprising masking blades configured to control a region of the patterning device that is illuminated by the beam of EUV radiation and wherein the electron beam source is between the masking blades and the patterning device.
   6. The lithographic apparatus of any of clauses 1 to 5, wherein the electron beam source comprises a wire, a comb or a pointed electrode.
   7. The lithographic apparatus of any of clauses 1 to 6, wherein the electron beam source is configured to emit electrons having kinetic energy <1 eV, desirably between about 0.05 eV and about 0.15 eV, to the part of the beam path adjacent the patterning surface.
   8. The lithographic apparatus of any of clauses 1 to 7, wherein the holder is configured to hold the patterning device in a state of electrical isolation.
   9. The lithographic apparatus of any of the preceding clauses, further comprising a voltage sensor configured to measure a potential of a patterning device held by the holder and a controller configured to turn off the electron beam source if the potential difference between the patterning device and a reference exceeds a threshold.
   10. The lithographic apparatus of any of the preceding clauses, further comprising a patterning device environment in which the patterning device is located, wherein the pressure within the patterning device environment is less than 10 Pa, and preferably less than 4 Pa.
   11. The lithographic apparatus of clause 10, further comprising an extraction module configured to cause a gas flow in the patterning device environment, desirably the gas flow is parallel to the patterning surface.
   12. A device manufacturing method comprising:
directing a beam of EUV radiation along a beam path to a patterning surface of a patterning device; and
emitting electrons toward the patterning surface and/or a part of the beam path adjacent the patterning surface.
   13. The method of clause 11, wherein the beam of EUV radiation is pulsed and the step of emitting electrons is performed between pulses of the beam of EUV radiation.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A lithographic apparatus comprising:
an illumination system configured to provide a beam of EUV radiation along a beam path;
a holder for a patterning device configured to impart a pattern to the beam of radiation, the patterning device comprising a patterning surface with a pattern thereon; and
an electron beam source configured to emit electrons toward the patterning surface and/or a part of the beam path adjacent the patterning surface, the electron beam source configured to emit electrons having kinetic energy less than 10 eV.

2. The lithographic apparatus of claim 1, wherein the electron beam source is configured to emit electrons having kinetic energy less than 5 eV.

3. The lithographic apparatus of claim 1, wherein the electron beam source is configured to emit electrons in pulses.

4. The lithographic apparatus of claim 3, wherein the electron beam source is configured to emit electrons during periods when the beam of EUV radiation is off.

5. The lithographic apparatus of claim 1, further comprising masking blades configured to control a region of the patterning device that is illuminated by the beam of EUV radiation and wherein the electron beam source is between the masking blades and the patterning device.

6. The lithographic apparatus of claim 1, wherein the electron beam source comprises a wire, a comb or a pointed electrode.

7. The lithographic apparatus of claim 1, wherein the electron beam source is configured to emit electrons having kinetic energy <1 eV, the part of the beam path adjacent the patterning surface.

8. The lithographic apparatus of claim 1, wherein the holder is configured to hold the patterning device in a state of electrical isolation.

9. The lithographic apparatus of claim 1, further comprising a voltage sensor configured to measure a potential of a patterning device held by the holder and a controller configured to turn off the electron beam source if the potential difference between the patterning device and a reference exceeds a threshold.

10. The lithographic apparatus of claim 1, further comprising a patterning device environment in which the patterning device is located, wherein the pressure within the patterning device environment is less than 10 Pa.

11. The lithographic apparatus of claim 10, further comprising an extraction module configured to cause a gas flow in the patterning device environment.

12. A device manufacturing method comprising:
directing a beam of EUV radiation along a beam path to a patterning surface of a patterning device; and
emitting electrons toward the patterning surface and/or a part of the beam path adjacent the patterning surface, wherein the electrons have kinetic energy less than 10 eV

13. The method of claim 11, wherein the beam of EUV radiation is pulsed and the step of emitting electrons is performed between pulses of the beam of EUV radiation.

14. The method of claim 11, wherein the electrons have kinetic energy less than 5 eV.

15. The method of claim 11, further comprising controlling a region of the patterning device that is illuminated by the beam of EUV radiation using one or more masking blades, wherein the electrons are emitted from between the masking blades and the patterning device.

16. The method of claim 11, wherein the electrons have kinetic energy less than 1 eV when provided to the part of the beam path adjacent the patterning surface.

17. The method of claim 11, further comprising measuring a potential of a patterning device held by the holder and discontinuing emitting the electrons responsive to the potential difference between the patterning device and a reference exceeding a threshold.

18. The method of claim 11, further comprising holding the patterning device in a state of electrical isolation.

19. The method of claim 11, wherein the patterning device is located in a patterning device environment and further comprising providing the pressure within the patterning device environment to be less than 10 Pa.

20. The method of claim 19, further comprising causing a gas flow in the patterning device environment.
